(19) United States
(12) Patent Application Publication
(10) Pub. No.: US 2011/0164765 A1
(43) Pub. Date: Jul. 7, 2011

(54) PRODUCT OR PACKAGING SYSTEM WITH INTEGRATED ELECTRONICS

(75) Inventors: Karen Korte, Miamisburg, OH (US); Robert Shelek, Xenia, OH (US); David Whitley, Dayton, OH (US); Michael G. Londo, Wake Forest, NC (US); Stephen L. Billups, Raleigh, NC (US); Michael Weston, Chapel Hill, NC (US); Zane Peterson, Burlington, NC (US)

(73) Assignee: MEADWESTVACO CORPORATION, Richmond, VA (US)

(21) Appl. No.: 13/003,593

(22) PCT Filed: Jul. 22, 2009
(86) PCT No.: PCT/US09/51365

§ 371 Date: Mar. 8, 2011

Related U.S. Application Data
(60) Provisional application No. 61/083,042, filed on Jul. 23, 2008.

(51) Int. Cl. H03F 99/00; G09D 3/00; G09D 3/12; B42D 5/04; H05K 5/00

(52) U.S. Cl. 381/120; 40/107; 361/724

(57) ABSTRACT

The present invention is directed to products, product packaging, or product displays containing an electrical component (30) integrated therein. The electrical component could be a lighting component (34), a sound component (36) or a combination of the two.

The present invention is directed to products, product packaging, or product displays containing an electrical component integrated therein. Such electrical component could be lights, sound or a combination of the two.

### BACKGROUND

Calendars, desk pads and planners are widely used to provide a quick and convenient indication of dates for planning purposes and the like. Notebooks are widely used to contain and organize materials. Many calendars, desk pads, planners, and notebooks include decorative features to create a pleasing visual appearance for the products. However, existing decorative features may not be sufficiently eye-catching for sales and display purposes. Furthermore, in dark settings such as a locker it may be difficult to see a calendar or to jot down a note or event in a planner or notebook.

In addition, product displays are constantly looking for new ways to catch consumers' eyes. Light and sound components that are inexpensively added and use minimal materials and interact with the consumer would be beneficial to market products. Medical packaging is also looking for ways to assist patient with the proper dosage and provide reminders to patients. Such a design could also be incorporated into medical packaging. Retailers are also searching for packaging improvements to the products themselves to increase sales and catch consumers' eyes. A thin inexpensive way to market products may be incorporated using the invention as described below.

### SUMMARY

In one embodiment the invention is a calender system including a calendar assembly including a plurality of pages, each page including a calendar portion printed thereon. The system further includes an electronics module coupled to the calendar assembly, wherein the electronics module is manually activatable to provide at least one of a sound output and/or a light output. Another embodiment of the invention is a notebook system including a binder capable of holding a plurality of papers or other attachable items. The notebook system further includes an electronics module coupled to the notebook assembly, wherein the electronics module is manually activatable to provide at least one of a sound output or a light output. Yet another embodiment of the invention is a planner system including a binder capable of holding a plurality of papers or other attachable items wherein at least one of the plurality of pages includes a calendar portion printed thereon. The planner system further includes an electronics module coupled to the planner assembly, wherein the electronics module is manually activatable to provide at least one of a sound output or a light output. Another embodiment of the invention is a desk pad system including a desk pad holder portion capable of holding a plurality of papers bound or unbound wherein at least one of the plurality of papers includes a calendar portion printed thereon. The desk pad system further includes an electronics module coupled to the desk pad assembly, wherein the electronics module is manually activatable to provide at least one of a sound output or a light output. Another embodiment of this invention would be to combine the light and sound component with medical packaging to warn when pills are missed or to determine if they should be taken either through the use of light or sound or both. Another embodiment of this invention would be to use a light and sound along with a packaging display either on a shelf or in a self standing unit. Another embodiment of this invention would be to use light and sound with a packaging for individual products themselves. Another embodiment of the invention could include an automatic activation feature wherein, light, pressure, sound, temperature motion and/or other indicators may activate the light and/or sound functions. Another embodiment of the invention may include a recording feature within the sound element. This feature would allow the user to make a message for his or herself or to allow someone else to leave a message for the user—such as a pharmacist reciting instructions for a particular medication.

### BRIEF DESCRIPTION OF THE DRAWINGS

FIG. 1 is a front perspective view of a calendar support;

FIG. 2 is a front perspective view of the calendar support of FIG. 1, shown in combination with an electronics module, a support panel, and an overlay;

FIG. 3 is a front and rear view of the overlay of FIG. 2;

FIG. 4 is a front perspective view of the support panel of FIG. 2, with the overlay, electronics module, and an acoustic panel coupled thereto; and

FIG. 5 is a front perspective view of the components of FIG. 4, with the support folded and a calendar assembly placed thereon.

FIG. 6 is a front perspective view of FIG. 5, with a pull tab to activate the light and/or sound function.

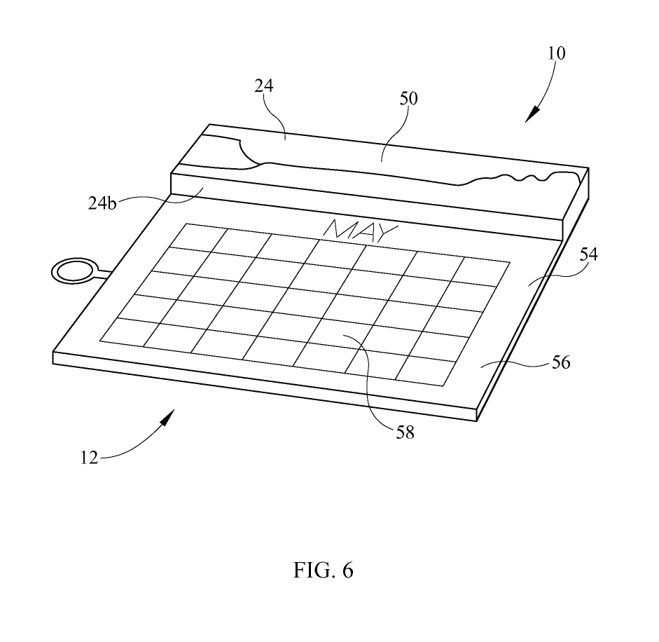

FIG. 7 is a front perspective view of FIG. 5, with a push button to activate the light and/or sound function.

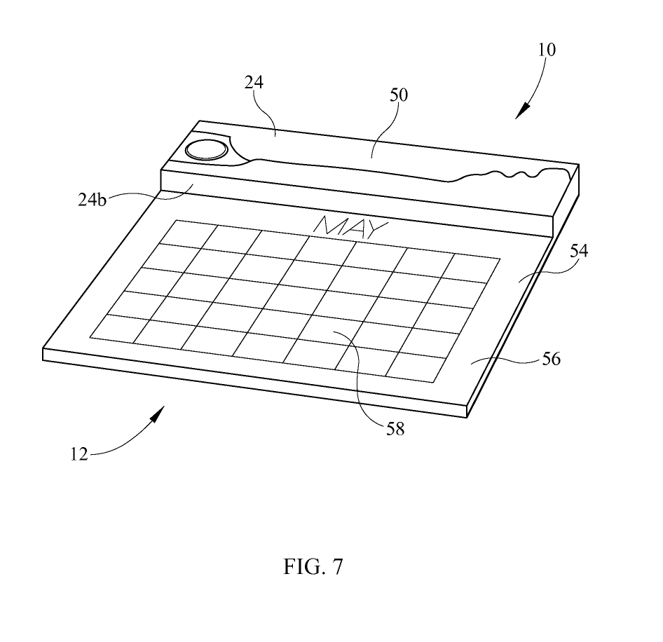

FIG. 8 is a display shown in combination with an electronics module, support panel, and overlay.

FIG. 9 is a front perspective view of the components of FIG. 8, with the products placed on the shelf and the overlay in place.

### DETAILED DESCRIPTION

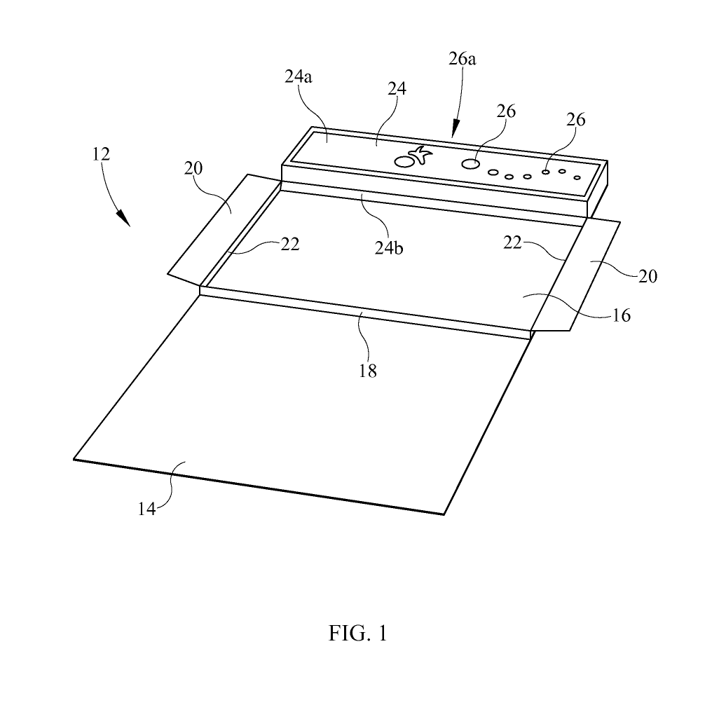

As shown in FIG. 1, in one embodiment the calendar, planner, notebook or desk pad system 10 includes a generally flat, sheet-like support 12 comprising a lower panel 14 and an upper panel 16 separated by a fold line 18. It is to be understood that the upper panel 16 may be located on to one side or at the bottom depending upon manufacturing preferences. The panels 14, 16 may each have about the same size and shape. A pair of side flaps 20 are positioned on either side of the upper panel 16, and each may extend generally the entire height of the upper panel 16 (i.e. generally in the vertical direction in the plane of FIGS. 1, 2 and 4). Each flap 20 may be separated from the upper panel 16 by a fold line 22 such that each flap 20 is pivotable or foldable about the associated fold line 22.

The support may include a collapsible box or folder 24 coupled to an upper edge of the upper panel 16. The box 24 may extend generally the entire length of the upper panel 16 (i.e. generally in the left-to-right direction of FIGS. 1, 2, 4 and 5), and may have a height less than the upper panel 16 (i.e. less than about ½, or less than about ¼ the height of the upper panel 16). Various surfaces (such as the top surface 24a, front surface 24b, etc.) of the box 24 may have a variety of openings or cut-outs 26 formed therein. Alternately, or in addition, various surfaces of the box 24 may include or be made of translucent and/or transparent material. The openings 26 and/or translucent portions allow light to shine therethrough, as will be described in greater detail below.

The side and/or end flaps of the box 24 may have fold lines integrated therein to allow the box 24 to be collapsed or folded flat, as shown in FIG. 1. Thus in one embodiment the box 24 is analogous to an expandble folder-style box used by photo processing department to store photographs for customer pickup. The foldable nature of the box 24 enables the support 12 to lie flat and therefore reduces storage space until the support 12 is ready for assembly.

The support 12 (including the lower panel 14, upper panel 16, and box 24) may be made of a single piece of material, such as cardboard, paperboard, plastic, or the like. In any case the support 12 may be made of relatively thin (i.e. less than ⅛″), light-weight, durable material. In the illustrated embodiment, the support 12 is made of a single, unitary seamless piece of material. However, the support 12 can also be made of various pieces of material joined together by adhesives, mechanical joining means (such as staples, stitching, etc.), sonic welding, etc.

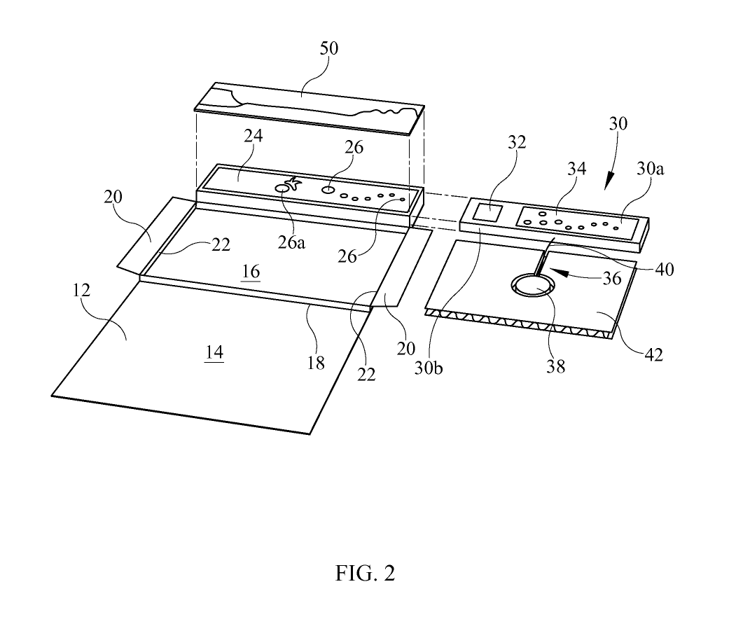

As shown in FIG. 2, the system 10 may include an electronics module 30 that may include a power source (not shown), an activator 32, a light source 34, and/or a sound source 36. The electronics module 30 may be sized to have about the same dimensions as the box 24. The power source may take the form of, or include, a battery or set of batteries, which may be replaceable to allow prolonged use of the electronics module 30. Alternately, the power source may be sealed due to the limited lifespan of the calendar system 10.

The light source 34 may be operatively coupled to the power source, and can include bulbs, LEDs, or other devices that convert electrical power into visible light. The light source 34 may include portions located on various surfaces of the electronics module 30, such as on the top surface 30a, the front surface 30b, or other surfaces. In this manner the light source 34 may have portions located thereon correspond in position to the openings 26/translucent portions of the box 24.

The sound source 36 may include a chip, electronics, or other media storage/memory devices (not shown) coupled to or housed inside the electronics module 30. The chip may be operatively coupled to the power source, and be configured to output a signal that takes the form of, or can be converted into, acoustic waves or audible sound. The chip may be able to record external sounds. The embodiment shown in FIG. 2, the chip of the sound source 36 is operatively coupled to a driver or amplifier 38 by a wire 40. The driver/amplifier 38 is received in an acoustic panel 42, which takes the form of a corrugated support in FIG. 2. The driver/amplifier 38 may be quite thin (i.e. less than about ½″, or less than about ¼″, in one embodiment) and fits within the thickness of the acoustic panel 42. When the amplifier 38 receives a signal from the chip, the amplifier 38 and support 42 cooperate to act as a speaker and create a physical manifestation of the electric audio signal in the form of an audible electronic signal/waves.

However, it should be understood that the acoustic panel 42 can take any of a variety of forms besides the corrugated support, such as various panels, supports, or other structures, to function as a speaker. In the illustrated embodiment, the acoustic panel 42 provides support and stiffness to the system 10 while also providing an acoustic output.

U.S. Pat. Nos. 6,519,347 and 7,174,025, the entire contents of which are hereby incorporated by reference, disclose speaker technology that may be utilized in or as the sound source 36. In any case, it should be understood that the electronic module 30 may include only a sound source 36 and not a light source 34, or vice versa, or may include both a sound source 36 and a light source 34. The activator 32 may be operatively coupled to the power source, and/or light source 34 and/or sound source 36 such that when the activator 32 is activated, the light source emits light 34 and/or the sound source 36 emits sounds.

In order to assemble the calendar system 10, the support 12 of FIG. 1 is provided and the box 24 is opened/propped in the position shown in FIG. 2. Once the box 24 is propped open the box 24 defines a cavity sized and configured to closely receive the electronics module 30 therein. In the illustrated embodiment, the assembled box 24 takes the form of a rectangular prism, such as a six-sided box. Even when assembled, however, the box 24 (and the electronics module 30) may be fairly flat, having a thickness (i.e. in a direction generally perpendicular to the plane of the support 12) that is less than about 10% of the length (or width) of the upper panel 16 to provide a relatively low-profile shape.

Next the power module 30 is inserted into the box 24, such as by sliding the electronics module 30 through the ends of the box 24 until the electronics module 30 is entirely received in the box 24. The electronics module 30 may be sized to be slightly larger than the box 24 such that the electronics module 30 is retained in the box 24 by frictional forces. Alternately, the box 24 is generally sealed to retain the electronics module 30 therein.

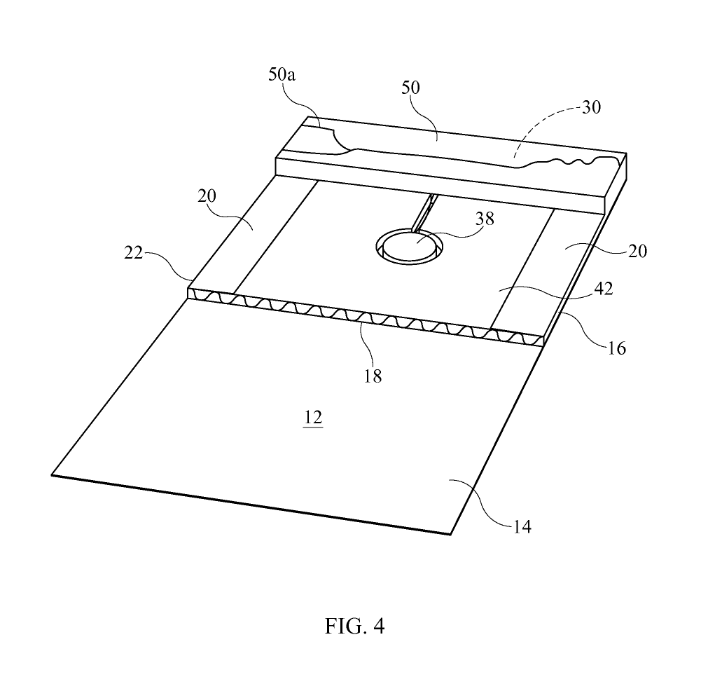

Next, the acoustic panel 42 is placed on the upper panel 16 of the support 12. The side flaps 20 of the support 12 are then pivoted about their fold lines 22 and fixed in place on top of the acoustic panel 42, such as by adhesives, mechanism joining means (staples, stitching, etc.) or by other means. If the chip of the sound source 36 is not already operatively coupled to the amplifier 38, the chip is then coupled to the amplifier 38, such as with the wire 40 or the like. The assembly shown in FIG. 4 is provided at this point. The lower panel 14 is then pivoted about the associated fold line 18 to cover, protect and physically isolate the acoustic panel 42. The lower panel 14 may then be fixed in place, such as by adhesives, mechanical joining means, etc.

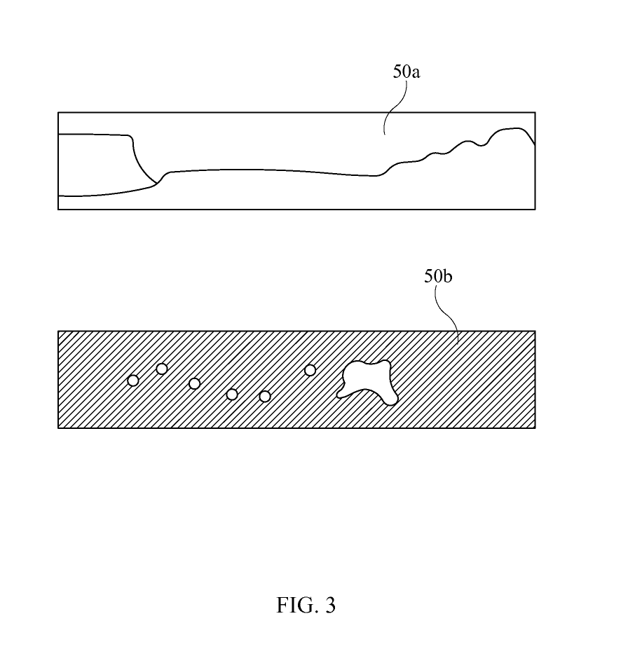

As shown in FIG. 2, an overlay or laminate 50 may be placed on top of the top surface 24a of the box 24 and coupled thereto by adhesives or the like. As shown in FIG. 3, the overlay 50 may be a generally flat, sheet-like material having two opposed sides 50a, 50b. The overlay 50 may be made of a generally translucent material, with different indicia printed on both sides 50a, 50b. In one embodiment, the indicia on the back side 50b of the overlay 50 generally corresponds to, or complements, the openings 26 in the top surface 24a of the box 24, and/or the light sources 34 on the top surface 30a of the electronics module 30. For example, the back side 50b of the overlay 50 may be generally coated with an opaque material, with portions of the opaque material being removed in areas that correspond to the openings 26 on the top surface 24a of the box 24. The front side 50a of the overlay 50 may be printed with indicia, graphics or images that are generally translucent.

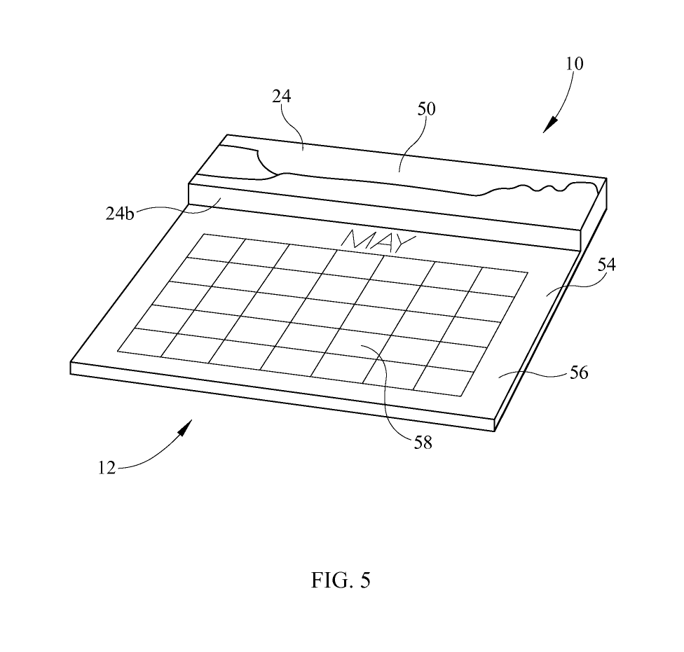

The calendar system 10 may also include a calendar assembly 54 (FIG. 5) including a plurality of calendar pages 56. After the lower panel 12 of FIG. 4 is pivoted over the upper panel 16, trapping the acoustic panel 42 therebetween, the calendar assembly 54 is placed on top of the lower panel 12 and fixed in place, such as by mechanical joining, adhesives or the like. Each calendar page 56 of the calendar assembly 54 may have a calendar portion 58 printed thereon, such as a monthly calendar portion. However, besides monthly calendars, the calendar portion 58 printed on each page 56 can be for any desired time frame, for example, weekly, daily, yearly, etc. The calendar pages 56 may be interfacially arranged and stacked in a sequential or chronological manner. Each page 56 of the calendar assembly 54 may be of generally the same size and shape.

Each page 56 of the calendar assembly 54 may be designed to be torn off (such as along a perforation line or the like) and separated from the remainder of the calendar assembly 56 to be discarded after the associated time period has passed. The calendar assembly 54 may be about the same size as the lower panel 14 of the support 12. The calendar assembly 50 can have a variety of sizes, such as a large size (13″×11″ in one embodiment, or larger), a small size (11″×7″ in one embodiment, or smaller), or various other sizes.

The resulting system 10, shown in FIG. 5, is a calendar system 10 with integrated electronics component. The electronics component includes but is not limited to a light source 34 and/or a sound source 36, and an activator 32 as shown in FIG. 2. The support 12, calendar assembly 54, overlay 50 and electronic module 30 may be designed with a common theme. For example, the support 12, calendar assembly 54, overlay 50 and electronic module 30 may have a theme associated with a particular movie, character, theme park, television show, actor, activity, association, geographic area, animal, item, person, etc. Indicia associated with the theme may be printed on the support 12, calendar assembly 54, and overlay 50. The common theme could also provide a product advertising message or a medical warning or indication.

In addition, the light source 34 and/or sound source 36 may output light and sound, respectively, associated with the theme. For example, if the theme is “underwater,” the openings 26 in the box 24 may take the form of progressively larger circles (in a right-to-left direction), representing bubbles, and terminating adjacent to a cut-out 26a of a fish jumping out of the water. The light source 34 may include various light source portions, or bulbs, with each bulb (or multiple bulbs) positioned below each opening 26 in the box 24. When the light source 34 is activated, the bulb under each opening 26, or “bubble,” may be triggered in a progressive manner (i.e. right-to-left in the illustrated embodiment), representing the rising of underwater bubbles. The translucent portion of the overlay 50 located above each opening 26 may colored blue to further reinforce the bubble/water image. The last light source to be activated may be positioned under the “jumping fish” cutout 26a.

Simultaneously, the sound source 36 may provide an output relating to the theme of the calendar system 10. For example, continuing with the “underwater” example above, the sound source 36 may output the sound of bubbles, the sound of gurgling water, a recording of a song associated with water, a recording of a voice describing bubbles or water, etc. Different sounds may be timed to coincide with the operation of differing light sources. For example, when the light source below the “jumping fish” image 26a is activated, the sound source 36 may output a “splashing” sound. In addition the sound source may be deigned to allow a user to record his or her own input, for example, a reminder or a message to oneself or one's child. This recording feature may have its own separate activator as described below.

The front side 50a of the overlay 50 may be printed with an image that relates to the theme of the calendar system 10. For example, continuing with the “underwater” example, the front side 50a of the overlay 50 may be printed with the image of waves on an ocean. During normal use (i.e., when the electronics module 30 is not activated), a viewer sees only with the image on the front side 50a of the overlay 50 (i.e. the waves on the ocean), and the image on the back side 50b of the overlay (the bubbles) is not visible due to the front-lighting of the calendar system 10. However, when the electronics module 30 is activated, the overlay 50 is back-lit by the light source 34, and the bubbles and other images on the back side 50b of the overlay 50 appear in dramatic fashion. It is to be understood that this idea of using a single overlay in combination with a light source may be used in more than just calendars, notebooks, planners, and/or desk pads. It could also be used in retail product displays, movie advertisement posters, or other products. An electronic component, a sound component, and/or a light component may be combined with a display unit to catch the consumer's attention. An activator as described below could also be added. In addition instead of a single overlay, a two piece or multi-piece construction could also be used to create the different shapes shown only when light is present behind them. It is to be understood that a film negative with images imprinted would also work to a similar effect.

The activator 32 may take a variety of forms, and may be manually activated or it may be automatically activation or It could be designed to be both manually activated or automatically activated. For example, in one case the activator 32 takes the form of a press button located on the electronics module 30. In this case, an opening may be provided in the box 24 to allow a user to access the button. However an access opening may not necessarily be provided in the box, in which case the user can simply press on, and slightly deform, the box 24 to apply sufficient pressure to the press button. The activator 32 can also take the form of a tag which hangs down from the electronics module 30 and which, when pulled, activates the sound 36 and/or light source 34. Further alternately, the activator 32 may take the form of a pull tab which protrudes outwardly from the side of the calendar system 10. This allows the activator 32 to be accessed from a variety of positions. The activator could also be pressure sensitive and located under where a product sits. Upon a product's removal the activator may initiate a light and/or sound response. The activator could also be triggered by temperature changes, by motion detection, by light changes, by a timer, by a signal from another device, by the opening or closing of a package, or by other means as chosen by manufacturing preferences.

The light source 34 may include light source portions on the front surface 30b of the electronics module 30 which project light through the front surface 24b of the box 24. In this case, when the light source 34 is activated the light source 34 directs light downwardly from the electronics module 30, and generally across the face of the calendar assembly 54. This feature may aid in viewing or writing on the calendar assembly 54 in low light conditions. The light source 34 portion on the front surface 30b of the electronics module 30 may be activatable separately from the other light source portions, or may be activated when the other light source portions are activated.

The electronics module 30 which may extend across the entire width of the calendar assembly 56/calendar system 10, can be utilized to provide an interesting and eye-catching display. The electronics module 30 may extend up to ¾ the length of the product or packaging structure. The electronics module 30 may extend up to ½ the length of the product or packaging structure. The electronics module 30 may extend up to ¼ the length of the product or packaging structure. The electronics module 30 may extend up to 1/10 the length of the product or packaging structure. The activator 32 may be able to be accessed and operated when the system 10 is displayed for sale, which allows a potential purchaser to activate the electronics module 30 so that the features of the calendar system 10 can be showcased. Moreover, if desired, the electronics module 30 may not necessarily be received inside the box 24, and instead the electronics module 30 may be exposed and directly coupled to the support 12 and/or calendar assembly 56. In this case, if desired, the electronic module 30 may have decorative indicia printed or carried directly thereon. If desired, the electronics module 30 may be configured to provide other outputs besides light or sound, such as vibrations, wireless signals, etc.

Attachment A includes photographs showing various embodiment of the invention.

While the above description focuses on the application of this light, sound, and aperture structure as it relates to a calendar product it is to be understood that a similar combination could be found useful for a variety of other products and industries. It is to be understood that a variety of materials and components could be combined. Or example the product or package including the aperture may be designed of paperboard or paperboard like components with a transparent overlay or it could be designed of plastic or plastic like components with a transparent overlay. It is to be understood that manufacturing preferences may dictate the materials used for the particular product.

It is to be understood that the above description of the lights and sounds may be combined with a notebook or planner It is to be understood that due to manufacturing preferences the components could be relocated so as to not inhibit writing within the notebook or planner. It is to be further understood that a more resistant material may be used to protect the light and sounds sources depending upon manufacturing preferences. It is to be understood that one or more sides of the notebook or planner cover may have the sound and light components contained within. It is to be understood that these components may be designed to lay in the spine of under the rings of said notebook or planner. It is to be understood that a similar design for the front or back covers would be used as for the calendar, though different structural materials may need to be present. It is to be understood that the light component may be designed to serve the functional purpose of shining down on the planner or notebook such that when lighting is poor the user is still able to see the contents of the notebook or planner. It is to be understood that the electronic module could be located on the top of the one or more covers displaying the light and/or sound, to either side or at the bottom. It is to be understood that a benefit may result from the electronic component being on the front cover to prevent possible inhibition of writing. It is to be understood that it may be preferred to locate the electronic component to the outer edge of the cover so as to decrease its inhibition of the spine and allow the cover to close more tightly. It is to be understood that a recording component could be added to the sound chip.

It is to be understood that a desk pad could be designed in a similar manner as the calendars containing a light and/or sound component as described above. More weight resistant materials may need to added depending upon manufacturing preferences due to the writing on the surface of the pad. The electronic module may be located at the top, at the bottom or on either of the two sides.

It is to be understood that medical packaging could also contain a similar light sound and image combination. The medical industry is responding to concerns of medicine misuse either through forgotten medication or overuse of medication with devices that provide indicators to patients that they should or should not use. Many of these indicators involve phone notification or lights within the package. This design would allow the notification to extend to the outer portion of the package. An energy source and light source could be added to a package as disclosed in U.S. patent application Ser. No. 12/025,439 herein incorporated by reference for such a purpose as described. This energy and light source can be arranged such that it interacts with apertures formed in the outer packaging. For example, such a design could indicate when medicine should be taken, by turning a light on that would shine through an aperture, designed as discussed herein, with a message or design to indicate to the patient that medicine should be taken. Such aperture could be given a green tint to encourage a patient to proceed and call attention to the package. In addition the power source could trigger a sound function to further catch the patients' attention through a beep or warning. In the instant where there is a concern that medication may be taken too early the power source and light could be triggered after a pill or dosage is consumed and after the package is closed the light could shine through an aperture stating a warning or notice or design to show that medicine should not be consumed until the light turns off and the message is removed. The outer packaging design could also be used to indicate when the package is fully closed such that the child-resistant element is fully engaged. In addition if a patient is unsure if he or she needs to take the medicine a calendar or time component could be lit on the box corresponding to the pill locations. If the pill area does not light up, due to the pill preventing light from shining through, the patient will know which pill they are on and be able to quickly determine if they should take a dosage. One potential design of this combination would be to use the battery and light pack as set forth in U.S. patent application Ser. No. 12/025,439 and the outer packaging over where the battery component is added would be used as the thick barrier to limit light source. The thin overlay to allow light through could be set just over this layer and also in the outer flap that fold over or just in the outer flap that folds over the main body of the package. This design may allow the outer label to interact with the interior package warning or notification system. The electrical component described in U.S. patent application Ser. No. 12/025,439 could also be applied to a variety of other products.

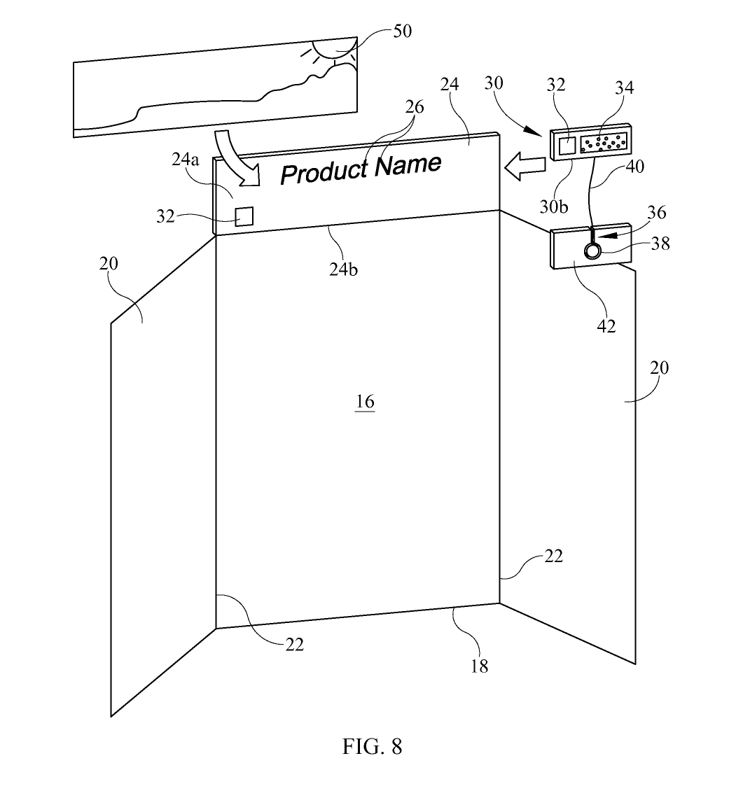

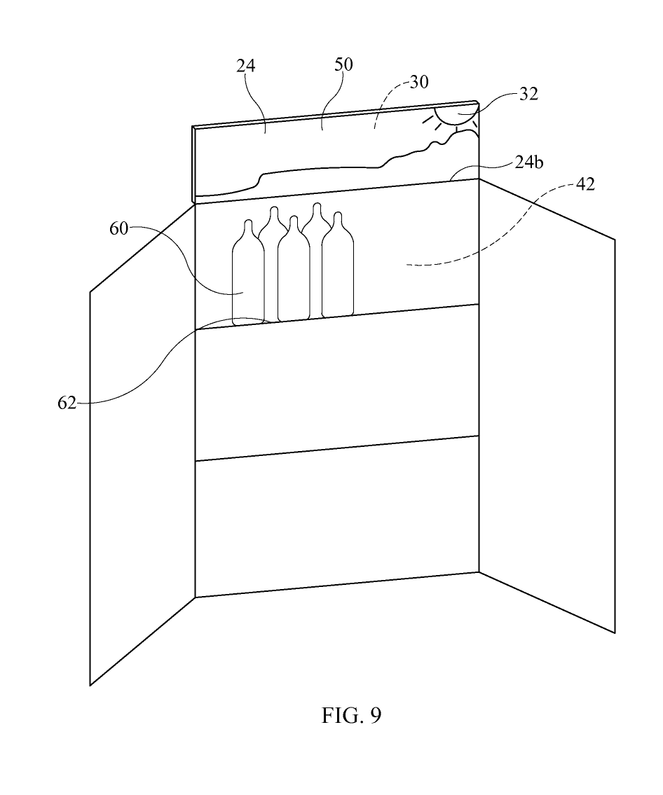

In addition, this design could also be used with product displays in a manner described above. A display would also be designed to possess a battery, light source, and/or sound source the size and location of which would depend upon manufacturing preferences. FIGS. 8-9 show a sample display configuration. The product name could be cut out so light can shine through the openings 26. Overlay 50 can be place on top to provide a decorative background setting on which to light the product name, advertising slogan or other indicia. Overlay 50 may have a design or indicia printed thereon. Overlay 50 may have two sides each printed with different indicia. The sound component 36 could be placed behind the shelves 62 where the product 60 will sit. Sides 20 could be folded in to cover the sound component 36. Additional side walls or other components present in traditional display units may be added based on manufacturing preferences. A light source 34 may be used to light up the indicia openings 26, such that the shine through the overlay 50. The activator 32 may be a push button, sound activated, motion activated, light activated or otherwise.

This design could also be used in packaging in general with a combination of power source, light, and/or sound depending upon manufacturing preferences. It is to be understood that the use of a solar strip may provide a small surface area capable of powering a small LED light capable of changing the image on the outer packaging of a product. The use of small components would reduce the space lost in the package for the products. It is to be understood that other small light, sound, and energy components could be added to a package to make it work in such a manner as described through the use of apertures in the packaging material itself. The positioning of the light source, energy source, and/or sound source may be determined by manufacturing preferences.

It is to be understood that this technology would also work on dry erase boards, through the use of transparent sections and non-transparent sections. It is to be understood that a variety of different products may utilize this technology.

It is to be understood that the electronic component could be designed to be smaller using small battery power sources or even solar energy strips. It is to be understood that the lighting could consist of small LED's or other small lighting components.

Having described the invention in detail and by reference to the various embodiments, it will be apparent that modifications and variations thereof are possible without departing from the scope of the invention.

1. A calender system comprising:
a calendar assembly including a plurality of pages, each page including a calendar portion printed thereon; and
an electronics module coupled to the calendar assembly, wherein the electronics module is activatable to provide at least one of a sound output or a light output.

2. The system of claim 1 wherein the calendar assembly includes a theme, and wherein the output of the electronics module is related to the theme.

3. The system of claim 1 wherein electronics modules is manually activatable to trigger a series of light sources in sequential order and coordinated with the output of the sound source.

4. The system of claim 1 wherein the electronics module includes a sound source, and wherein the system further includes an acoustic panel coupled to and generally supporting the calendar assembly thereon, the acoustic panel being operatively coupled to an amplifier and to the sound source such that when the amplifier receives a signal from the sound source, the amplifier and acoustic support cooperate to act as a speaker and create a physical manifestation of the signal in the form of an audible signal.

5. A display system comprising:
a display assembly including one or more shelves; and
an electronics module coupled to the display assembly, wherein the electronics module is activatable to provide at least one of a sound output or a light output.

6. The system of claim 5, wherein the display assembly includes a theme, and wherein the output of the electronics module is related to the theme.

7. The system of claim 5, wherein electronics modules is manually activatable to trigger a series of light sources in sequential order and coordinated with the output of the sound source.

8. The system of claim 5, wherein the electronics module includes a sound source, and wherein the system further includes an acoustic panel coupled to and generally supporting the display assembly thereon, the acoustic panel being operatively coupled to an amplifier and to the sound source such that when the amplifier receives a signal from the sound source, the amplifier and acoustic support cooperate to act as a speaker and create a physical manifestation of the signal in the form of an audible signal.
